(19) United States
(12) Patent Application Publication
(10) Pub. No.: US 2007/0120146 A1
(43) Pub. Date: May 31, 2007

(54) DIFFERENTIAL INPUT/OUTPUT DEVICE INCLUDING ELECTRO STATIC DISCHARGE (ESD) PROTECTION CIRCUIT

(76) Inventors: Chyh-Yih Chang, Taipei County (TW); Yan-Nan Li, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,071

(22) Filed: Jan. 23, 2006

(30) Foreign Application Priority Data
Nov. 25, 2005 (TW) 94141422

(51) Int. Cl. H01L 29/74

(52) U.S. Cl. 257/173

(57) ABSTRACT

A differential input/output device including an electro static discharge protection circuit is provided. The differential input/output device includes a P-type differential pair. The P-type differential pair includes two P-type transistors. The gate of each P-type transistor is coupled to an N-type transistor to protect the P-type transistor when CDM ESD occurs. Compared with the conventional technology, the protection device of the present invention provides a lower impedance current path when CDM ESD occurs in the input device.

### CROSS-REFERENCE TO RELATED APPLICATION

This application claims the priority benefit of Taiwan application Ser. No. 94141422, filed on Nov. 25, 2005. All disclosure of the Taiwan application is incorporated herein by reference.

### BACKGROUND OF THE INVENTION

1. Field of Invention

The present invention relates to a differential input/output device including an electro static discharge (ESD) protection circuit. More particularly, the present invention relates to a P-type differential input/output circuit using an N-type protection device to prevent CDM ESD.

2. Description of Related Art

Nowadays, differential input/output structure plays a very important role in IC products to transmit data quickly and achieve low voltage and low power consumption. Differential input/output structure, e.g. Reduced Swing Differential Signaling (RSDS) and Low Voltage Differential Signaling (LVDS), provides many advantages such as low power consumption, reduced electromagnetic interference (EMI), increased noise resistance, and fast data transmission.

However, this kind of structure usually uses deep submicron CMOS technology in manufacturing process and provides better performance through smaller size of gate length. However, thinner gate oxide may damage transistors, especially when CDM ESD occurs.

FIG. 1A and FIG. 1B are diagrams illustrating an ESD protection circuit according to U.S. Pat. No. 6,885,529. An additional protection device (N-type transistor 101A/diode 101B) is disposed between the gate of the input/output N-type transistor 111 and the power cord VSS, and an additional protection device (P-type transistor 102A/diode 102B) is disposed between the gate of the input/output P-type transistor 112 and the power cord VDD. Even this kind of protection circuit is applicable to common input/output devices, it is not applicable to differential input/output devices because the body of the P-type transistor used as the protection device has to be coupled to the power cord VDD while the body of the P-type transistor used as the input stage can not be coupled to the power cord VDD. The P-type transistor used as the protection device is invalid when CDM ESD occurs because there is large junction breakdown voltage between the protection device and the protected device (P-/N-well).

FIG. 2 is a diagram illustrating a CDM ESD protection circuit according to U.S. Pat. No. 6,437,407 disclosed in U.S. by Industrial Technology Research Institute of Taiwan (ROC). The actual protection circuit includes a pair of CDM dampers 222 and 222′ respectively coupled to CMOS transistors 224 and 224′. This structure can not be applied to differential pair structure since a current source is required between the power cord VDD and the P-type differential pair even though the CDM dampers 222 and 222′ can effectively clamp the overstress voltage of the thin oxide spanning over the input stage when CDM occurs.

FIG. 3 is a diagram illustrating a CDM ESD protection circuit being applied in a differential input circuit according to U.S. Pat. No. 6,437,407 disclosed in U.S. by Industrial Technology Research Institute of Taiwan (ROC). Since the voltage difference between the source and the body of the N-type transistor 301 is not voltage level 0, the device will be affected by body effect and the performance of the input stage will be reduced. In addition, FIG. 4 is a diagram illustrating a CDM ESD protection circuit according to U.S. Pat. No. 5,901,022 disclosed in U.S. by Industrial Technology Research Institute of Taiwan (ROC). An inductor 401 is disposed between the input stage and the pad. However, LC surge is produced by the inductor 401 and the parasitic capacitance of the metal oxide semiconductor field effect transistor 402 of the input stage circuit when the circuit is operating at high speed. Thus, the structure which uses an inductor as CDM ESD protection circuit according to U.S. Pat. No. 5,901,022 can not be applied to a high-speed differential input/output device such as RSDS and LVDS.

### SUMMARY OF THE INVENTION

Accordingly, the present invention is directed to provide a differential input/output device including ESD protection circuit used for preventing CDM ESD in the differential input/output device from damaging the circuit.

The present invention provides a differential input/output device including ESD protection circuit. The differential input/output device includes a current source, a first P-type transistor, a second P-type transistor, a first ESD protection unit, and a second ESD protection unit. The current source is used for providing a current. The first terminal and the body of the first P-type transistor are coupled to the current source. The first terminal and the body of the second P-type transistor are coupled to the current source. The first ESD protection unit includes a first N-type transistor having its first terminal coupled to the gate of the first P-type transistor. The gate of the first N-type transistor is coupled to the second terminal and the body of the first N-type transistor, wherein when CDM electrostatic current occurs in the body of the first P-type transistor, the first N-type transistor provides a current path from the body to the first terminal of the first N-type transistor to prevent the electrostatic current from fusing the gate oxide of the first P-type transistor. The second ESD protection unit includes a second N-type transistor having its first terminal coupled to the gate of the second P-type transistor. The gate of the second N-type transistor is coupled to the second terminal and the body of the second N-type transistor, wherein when CDM electrostatic current occurs in the body of the second P-type transistor, the second N-type transistor provides a current path from the body to the first terminal of the second N-type transistor to prevent the electrostatic current from fusing the gate oxide of the second P-type transistor.

In the differential input/output device including ESD protection circuit according to an exemplary embodiment of the present invention, the foregoing first P-type transistor and first N-type transistor are disposed on a P-type substrate. The first P-type transistor includes: an N-well disposed in the P-type substrate; a first gate disposed on the N-well; a first P+ doped region disposed in the N-well at one side of the first gate and served as the first terminal of the first P-type transistor; a second P+ doped region disposed in the N-well at another side of the first gate and served as the second terminal of the first P-type transistor; a first gate dielectric layer disposed between the N-well and the first gate; a first N+ doped region disposed in the N-well. The first N-type transistor includes: a P-well disposed in the P-type substrate and outside of the N-well; a second gate disposed on the P-well; a second N+ doped region disposed in the P-well and at one side of the second gate close to the N-well and served as the first terminal of the first N-type transistor; a third N+ doped region disposed in the P-well and at another side of the second gate and served as the second terminal of the first N-type transistor; a second gate dielectric layer disposed between the P-well and the second gate; a third P+ doped region disposed in the P-well.

In the differential input/output device including ESD protection circuit according to an exemplary embodiment of the present invention, the foregoing second P-type transistor and second N-type transistor are disposed on a P-type substrate. The second P-type transistor includes: an N-well disposed in the P-type substrate; a first gate disposed on the N-well; a first P+ doped region disposed in the N-well at one side of the first gate and served as the first terminal of the second P-type transistor; a second P+ doped region disposed in the N-well at another side of the first gate and served as the second terminal of the second P-type transistor; a first gate dielectric layer disposed between the N-well and the first gate; a first N+ doped region disposed in the N-well. The second N-type transistor includes: a P-well disposed in the P-type substrate and outside of the N-well; a second gate disposed on the P-well; a second N+ doped region disposed in the P-well and at one side of the second gate close to the N-well and served as the first terminal of the second N-type transistor; a third N+ doped region disposed in the P-well and at another side of the second gate and served as the second terminal of the second N-type transistor; a second gate dielectric layer disposed between the P-well and the second gate; a third P+ doped region disposed in the P-well.

According to embodiments of the present invention, a P-type transistor differential pair is adopted in the differential input/output device, wherein the P-type differential pair includes two P-type transistors, the gate of each P-type transistor is coupled to a protection device formed by an N-type transistor, so as to protect the P-type transistor from being damaged by CDM ESD. A lower impedance current path can be further provided when CDM ESD occurs in the differential input/output device.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are diagrams illustrating an ESD protection circuit according to U.S. Pat. No. 6,885,529.

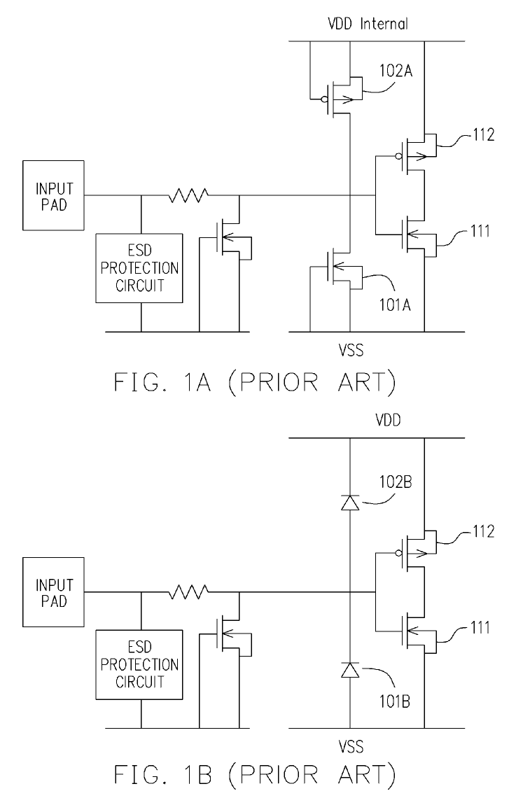

FIG. 2 is a diagram illustrating a CDM ESD protection circuit according to U.S. Pat. No. 6,437,407 disclosed in U.S. by Industrial Technology Research Institute of Taiwan (ROC).

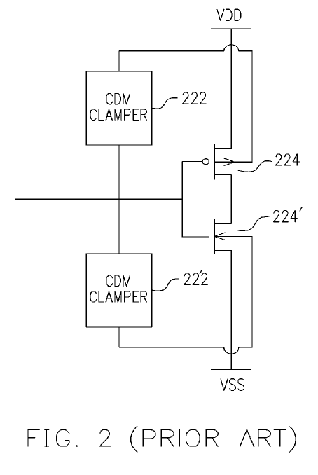

FIG. 3 is a diagram illustrating a CDM ESD protection circuit being applied in a differential input circuit according to U.S. Pat. No. 6,437,407 disclosed in U.S. by Industrial Technology Research Institute of Taiwan (ROC).

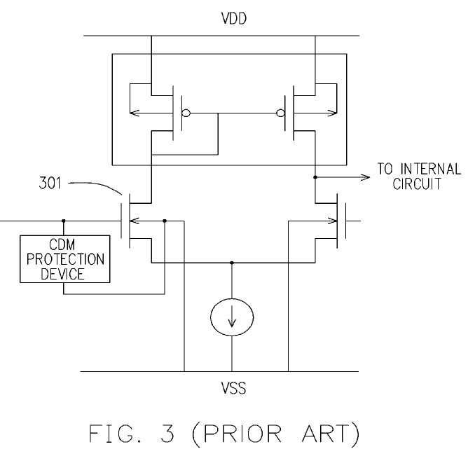

FIG. 4 is a diagram illustrating a CDM ESD protection circuit according to U.S. Pat. No. 5,901,022 disclosed in U.S. by Industrial Technology Research Institute of Taiwan (ROC).

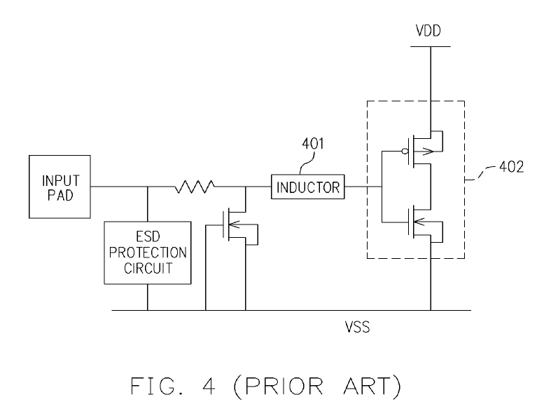

FIG. 5 is a circuit diagram of a differential input/output device including ESD protection circuit according to an embodiment of the present invention.

FIG. 6 is a cross-sectional view of a first P-type transistor and a first N-type transistor in a differential input/output device including ESD protection circuit on the IC chip according to an embodiment of the present invention.

FIG. 7 is a cross-sectional view of a conventional differential input/output device including a CDM ESD protection circuit on the chip.

FIG. 8 is a circuit diagram of a differential input/output device including ESD protection circuit according to an embodiment of the present invention.

FIG. 9 is a circuit diagram of a differential input/output device including ESD protection circuit according to an embodiment of the present invention.

FIG. 10 is a circuit diagram of a differential input/output device including ESD protection circuit according to an embodiment of the present invention.

FIG. 11 is a circuit diagram of a differential input/output device including ESD protection circuit according to an embodiment of the present invention.

FIG. 12 is a circuit diagram of a differential input/output device including ESD protection circuit according to an embodiment of the present invention.

### DESCRIPTION OF EMBODIMENTS

Since the conventional technology cannot be used for protecting P-type differential input/output device when CDM ESD occurs, the present invention provides a differential input/output device including a CDM ESD protection circuit. The detailed embodiments thereof are described in detail below with reference to the accompanied drawings.

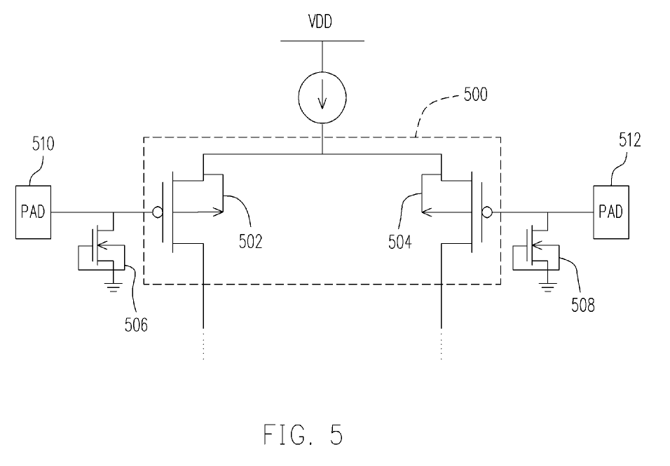

FIG. 5 is a circuit diagram of a differential input/output device including ESD protection circuit according to an embodiment of the present invention. The differential input/output device provides a lower impedance current path when CDM ESD occurs. Referring to FIG. 5, the differential input/output device including ESD protection circuit includes a P-type transistor differential pair 500, a first ESD protection unit and a second ESD protection unit. In the present embodiment, the first and the second ESD protection units respectively include N-type transistors 506 and 508. Wherein, the bodies of the P-type transistors 502 and 504 are not connected to the power cord VDD directly. The sources of the protection devices N-type transistors 506 and 508 are grounded and the drains thereof are coupled to the gates of the P-type transistors 502 and 504. When CDM ESD occurs in the P-type transistor 502, the voltage level of the electric charge will cause junction breakdown between the drain and the body of the N-type transistor 506, so as to provide a CDM current path from the body of the N-type transistor 506 to the pad 510. Similarly, when CDM ESD occurs in the P-type transistor 504, the current path from the body of the N-type transistor 508 to the pad 512 is provided in the same way. When the input/output device works properly, the N-type transistors 506 and 508 are turned off since the gates and sources of the N-type transistors 506 and 508 are coupled with each other. However, even the gates, sources, and bodies of the N-type transistors 506 and 508 are grounded in the present embodiment, they can be designed as being coupled to a suitable voltage.

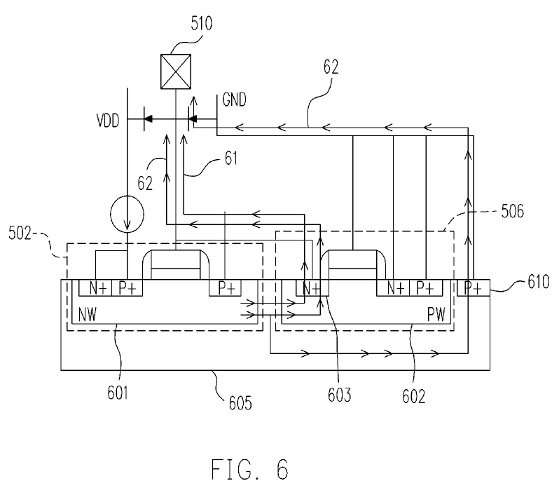

FIG. 6 is a cross-sectional view of a first P-type transistor 502 and a first N-type transistor 506 in a differential input/output device including ESD protection circuit on the IC chip according to an embodiment of the present invention. Referring to FIG. 6, the CDM current paths (61 and 62 as shown) are also illustrated in the figure. In the present embodiment, when CDM negative charge electrostatic current occurs, the negative charge in the N-well 601 of the P-type transistor 502 to be protected goes into the P-well 602 of the N-type transistor 506, so that the PN junction between the N+ doped region 603 disposed in the P-well 602 and the P-well 602 breaks down. After the junction breakdown, the negative charge is led out of the pad 510 through path 61.

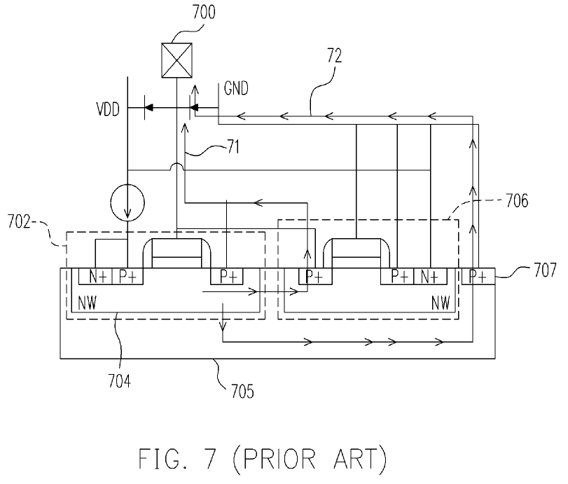

To explain the embodiment of the present invention in FIG. 6 in more detail, a conventional CDM ESD protection circuit will be described here as an example. FIG. 7 is a cross-sectional view of a conventional differential input/output device including CDM ESD protection circuit on the chip. It can be seen that the difference between FIG. 7 and FIG. 6 is that a P-type transistor 706 is used as the protection circuit in FIG. 7. Similarly, the negative charge in the N-well 704 of the input/output device P-type transistor 702 will cause junction breakdown between the P-type substrate 705 and the N-well 704 (path 71). The junction breakdown voltage between the P-type substrate 705 and the N-well is much greater than the junction breakdown voltage between the N+ doped region 603 and the P-well 602 in FIG. 6 because the dopant in the P-type substrate 705 is smaller than the dopant in the N-well 704. Therefore, the turn-on efficiency of the embodiment in FIG. 6 is better than that of the embodiment in FIG. 7.

As to the situation of storing positive charge in the P-type transistor of the device to be protected, conventionally, as in FIG. 7, the positive charge will cause junction breakdown between the N-well 704 and the P-type substrate 705; and furthermore, some charges pass through the Psub pickup 707 to reach the pad 700; some charges reach the pad 700 by breaking down the junction between the N-well and the P+ doped region (path 72). In the embodiment of the present invention as shown in FIG. 6, some charges pass through the Psub pickup 610 to reach the pad 510, as shown in FIG. 7; some other charges reach the pad 510 by breaking down the junction between the P-type substrate 605 and the P-well 602 (path 62). Since the junction breakdown voltage between the P-type substrate 605 and the P-well 602 is very small, the charges can pass through easily to reach the pad 510. Accordingly, when CDM ESD occurs, the present invention can more effectively protect the input/output circuit from being damaged compared to the conventional method regardless whether positive charge or negative charge is stored in the transistor of the device.

Similarly, it should be understood by those skilled in the art that the embodiment structure of P-type transistor 504 and N-type transistor 508 can also be implemented as the layout of P-type transistor 502 and N-type transistor 506 in FIG. 6, so the detail is not described again.

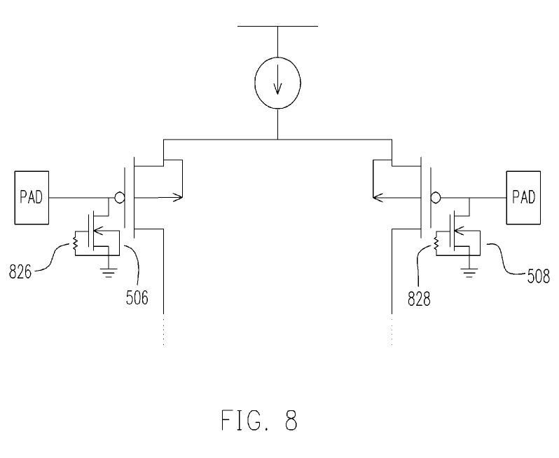

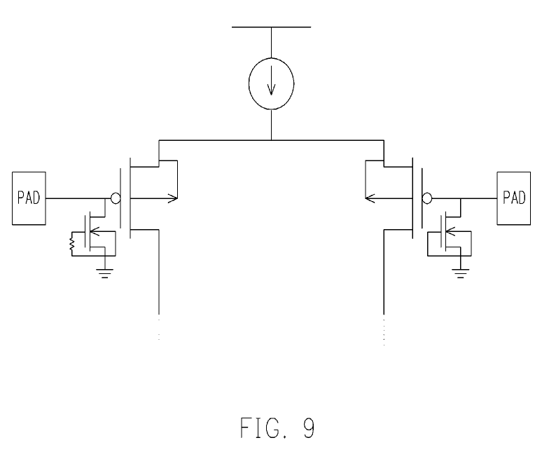

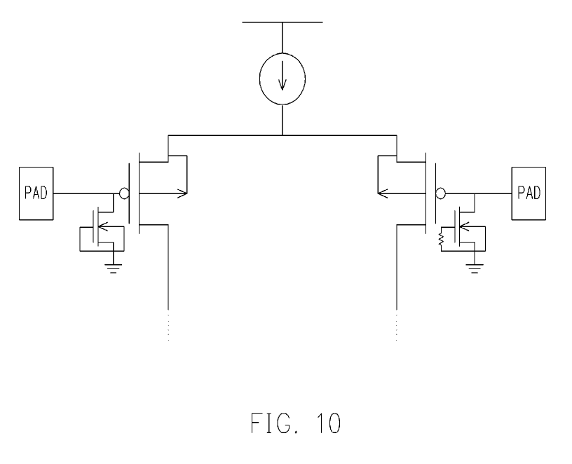

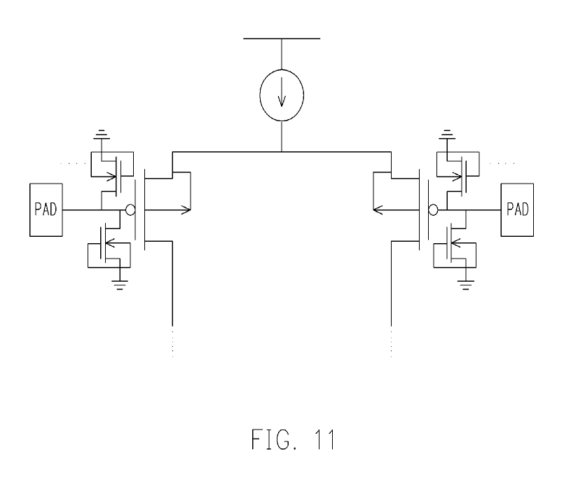

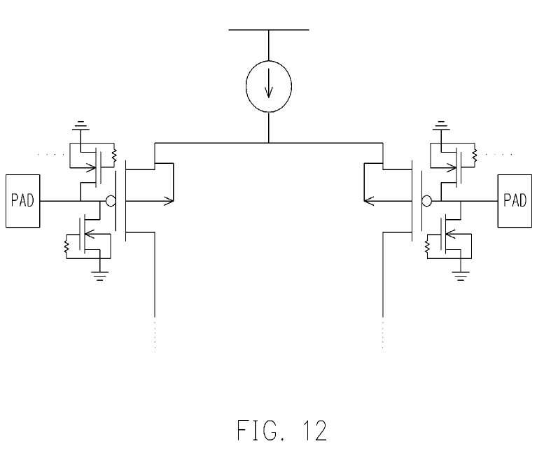

The coupling of the gate of the ESD protection device N-type transistor can be adjusted according to different requirements. FIG. 8 is a circuit diagram of a differential input/output device including ESD protection circuit according to an embodiment of the present invention. The gates of the two N-type transistors 506 and 508 can be respectively coupled to the bodies thereof through resistors 826 and 828. Similarly, the present invention can also be implemented as illustrated in FIGS. 9 and 10. The embodiments in FIGS. 9 and 10 are similar to that in FIG. 8 and the difference is that only the gate of one of the N-type transistors has a resistor connected. Similarly, the present invention can be implemented as illustrated in FIG. 11, that is, the gate of each P-type transistor is respectively coupled with two N-type transistors. The embodiment illustrated in FIG. 12 is derived from the embodiment in FIG. 11. In the circuit illustrated in FIG. 12, the gate of each N-type transistor has a resistor connected. In addition, it should be understood by those skilled in the art that FIG. 12 is only one embodiment of the present invention, the other embodiments can be implemented as, for example, attaching a resistor to the gate of one of the N-type transistors, attaching resistors to the gates of two of the N-type transistors, or attaching resistors to the gates of three of the N-type transistors, which are all within the scope of the present invention.

In overview, a P-type transistor differential pair is adopted in the differential input/output circuit of the present invention, the gate of each P-type transistor is coupled to the protection device formed by an N-type transistor, so as to protect the P-type transistor from CDM ESD. A lower impedance current path can be further provided when CDM ESD occurs in the differential input/output device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A differential input/output device including ESD protection circuit, comprising:
a first P-type transistor, having its first terminal and body coupled to a current source; a second P-type transistor, having its first terminal and body coupled to the current source; a first ESD protection unit, comprising:
a first N-type transistor, having its first terminal coupled to the gate of the first P-type transistor and its gate coupled to the second terminal and the body of the first N-type transistor, wherein when a CDM electrostatic current occurs in the body of the first P-type transistor, the first N-type transistor provides a current path from the body to the first terminal of the first N-type transistor; and
a second ESD protection unit, comprising:
a second N-type transistor, having its first terminal coupled to the gate of the second P-type transistor and its gate coupled to the second terminal and the body of the second N-type transistor, wherein when a CDM electrostatic current occurs in the body of the second P-type transistor, the second N-type transistor provides a current path from the body to the first terminal of the second N-type transistor.

2. The differential input/output device as claimed in claim 1, wherein the second terminal of the first N-type transistor is coupled to a first voltage.

3. The differential input/output device as claimed in claim 2, wherein the first voltage is ground voltage.

4. The differential input/output device as claimed in claim 1, wherein the first ESD protection unit further includes: a resistor, coupled between the gate and the second terminal of the first N-type transistor.

5. The differential input/output device as claimed in claim 1, wherein the second ESD protection unit further includes:
a resistor, coupled between the gate and the second terminal of the second N-type transistor.

6. The differential input/output device as claimed in claim 1 further comprising: a third ESD protection unit, comprising:
a third N-type transistor, having its first terminal coupled to the gate of the first P-type transistor and its gate coupled to the second terminal and the body of the third N-type transistor, wherein when a CDM electrostatic current occurs in the body of the first P-type transistor, the third N-type transistor provides a current path from the body to the first terminal of the third N-type transistor to prevent the electrostatic current from fusing the gate oxide of the first P-type transistor.

7. The differential input/output device as claimed in claim 6, wherein the third ESD protection unit further comprises:
a resistor, coupled between the gate and the second terminal of the third N-type transistor.

8. The differential input/output device as claimed in claim 6, wherein the second terminal of the third N-type transistor is grounded.

9. The differential input/output device as claimed in claim 1 further comprising: a fourth ESD protection unit, comprising:
a fourth N-type transistor, having its first terminal coupled to the gate of the second P-type transistor and its gate coupled to the second terminal and the body of the fourth N-type transistor, wherein when a CDM electrostatic current occurs in the body of the second P-type transistor, the fourth N-type transistor provides a current path from the body to the first terminal of the fourth N-type transistor to prevent the electrostatic current from fusing the gate oxide of the second P-type transistor.

10. The differential input/output device as claimed in claim 9, wherein the fourth ESD protection unit further comprises:
a resistor, coupled between the gate and the second terminal of the fourth N-type transistor.

11. The differential input/output device as claimed in claim 9, wherein the second terminal of the fourth N-type transistor is grounded.

12. The differential input/output device as claimed in claim 1, wherein the first P-type transistor and the first N-type transistor are disposed on a P-type substrate, the first P-type transistor comprising:
an N-well, disposed in the P-type substrate;
a first gate, disposed on the N-well;
a first P+ doped region, disposed in the N-well at one side of the first gate and served as the first terminal of the first P-type transistor;
a second P+ doped region, disposed in the N-well at another side of the first gate and served as the second terminal of the first P-type transistor;
a first gate dielectric layer, disposed between the N-well and the first gate; and
a first N+ doped region, disposed in the N-well; and the first N-type transistor comprising:
a P-well, disposed in the P-type substrate and outside of the N-well;
a second gate, disposed on the P-well;
a second N+ doped region, disposed in the P-well and at one side of the second gate close to the N-well, served as the first terminal of the first N-type transistor;
a third N+ doped region, disposed in the P-well and at another side of the second gate, served as the second terminal of the first N-type transistor;
a second gate dielectric layer, disposed between the P-well and the second gate; and
a second P+ doped region, disposed in the P-well.

13. The differential input/output device as claimed in claim 1, wherein the second P-type transistor and the second N-type transistor are disposed on a P-type substrate, the second P-type transistor comprising:
an N-well, disposed in the P-type substrate;
a first gate, disposed on the N-well;
a first P+ doped region, disposed in the N-well at one side of the first gate and served as the first terminal of the second P-type transistor;
a second P+ doped region, disposed in the N-well at another side of the first gate and served as the second terminal of the second P-type transistor;
a first gate dielectric layer, disposed between the N-well and the first gate; and
a first N+ doped region, disposed in the N-well; and the second N-type transistor comprising:
a P-well, disposed in the P-type substrate and outside of the N-well;
a second gate, disposed on the P-well;
a second N+ doped region, disposed in the P-well and at one side of the second gate close to the N-well, served as the first terminal of the second N-type transistor;
a third N+ doped region, disposed in the P-well and at another side of the second gate, served as the second terminal of the second N-type transistor;
a second gate dielectric layer, disposed between the P-well and the second gate; and
a third P+ doped region, disposed in the P-well.
